(19) United States
(12) Patent Application Publication
(10) Pub. No.: US 2010/0007020 A1
(43) Pub. Date: Jan. 14, 2010

(54) SEMICONDUCTOR DEVICE AND METHOD OF MANUFACTURING THE SAME

(75) Inventor: Yukio Takigawa, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/495,201

(22) Filed: Jun. 30, 2009

(30) Foreign Application Priority Data
Jul. 11, 2008 (JP) 2008-181182

(51) Int. Cl. H01L 23/532; H01L 21/768

(52) U.S. Cl. 257/741; 438/618; 257/E23.161; 257/E21.584

(57) ABSTRACT

A semiconductor device includes: an insulating film including a porous insulating material and formed above a substrate; an interconnection wire including copper and buried in a groove formed at least in an obverse surface of the insulating film; and a barrier insulating film including an insulating material containing a nitrogen heterocyclic compound and formed over the insulating film and the interconnection wire.

### CROSS-REFERENCE TO RELATED APPLICATIONS

This application is based upon and claims the benefit of priority of the prior Japanese Patent Application No. 2008-181182, filed on Jul. 11, 2008, the entire contents of which are incorporated herein by reference.

### FIELD

The present invention relates to a semiconductor device and a method of manufacturing the same. More particularly, the present invention relates to a semiconductor device having a porous insulating film, and a method of manufacturing the same.

### BACKGROUND

With increasing integration and improving device density of semiconductor integrated circuits, increasing demand exists for more multilayered semiconductor devices. On the other hand, the spacing of interconnect is becoming smaller with growing integration, resulting in the problem of wiring delay due to an increased interconnects capacitance.

A wiring delay T, which is subject to the effects of interconnect resistance and interconnect capacitance, is expressed as: T∝CR, where R represents the interconnect resistance and C represents the interconnects capacitance. Based on this expression, the interconnects capacitance C is expressed as C=ε₀εᵣS/d, where d represents an interconnect spacing, S represents an electrode area (the area of side surfaces of opposed interconnection wires), εᵣ represents the dielectric constant of an insulating material provided between adjacent interconnection wires, and ε₀ represents the dielectric constant of a vacuum. Therefore, lowering the dielectric constant of an insulating film is effective in reducing the wiring delay.

Such insulating materials heretofore used include an inorganic film, such as of silicon dioxide (SiO₂), silicon nitride (SiN) or phosphosilicate glass (PSG), and an organic polymer such as polyimide. However, a CVD-SiO₂ film formed by CVD, which is most frequently used in semiconductor devices, has a dielectric constant of about 4. An SiOF film, which is being studied as a low dielectric constant CVD film, has a dielectric constant of about 3.3 to about 3.5, but exhibits high moisture absorption. The dielectric constant of the SiOF film rises undesirably with increasing absorption of moisture.

In recent years, attention has been focused on a porous insulating film as an insulating material having an even lower relative permittivity. Such a porous insulating film is an insulating film having a plurality of pores therein.

### SUMMARY

According to aspects of an embodiment, a semiconductor device includes: an insulating film including a porous insulating material and formed above a substrate; an interconnection wire including copper and buried in a groove formed at least in an obverse surface of the insulating film; and a barrier insulating film including an insulating material containing a nitrogen heterocyclic compound and formed over the insulating film and the interconnection wire.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic sectional view illustrating a structure of a semiconductor device according to one embodiment; and

FIGS. 2A to 2L are sectional views illustrating processes of a method of manufacturing a semiconductor device according to one embodiment.

### DESCRIPTION OF EMBODIMENTS

A porous insulating material has a relative permittivity lowered by the provision of pores therein. Such a porous insulating material having pores therein, however, has a low strength and hence may be susceptible to damage by plasma during film deposition when a CVD-type insulating film is formed thereon. When damaged, the porous insulating film may have deteriorated properties including an increased relative permittivity and a lower insulating property.

The semiconductor device disclosed herein makes it possible to reduce damage to an insulating film including the porous material during formation of a barrier insulating film serving to prevent diffusion of copper from interconnection wires. Thus, it is possible to prevent a rise in the dielectric constant of the insulating film including the porous material and deterioration in the insulating property of the insulating film. Thus, a semiconductor device having a low interconnect capacitance and a high insulating property may be realized.

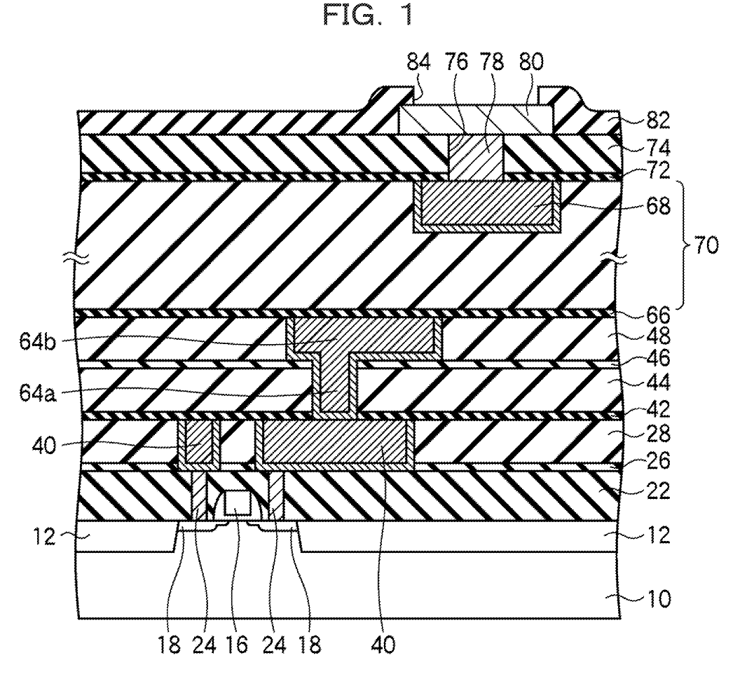

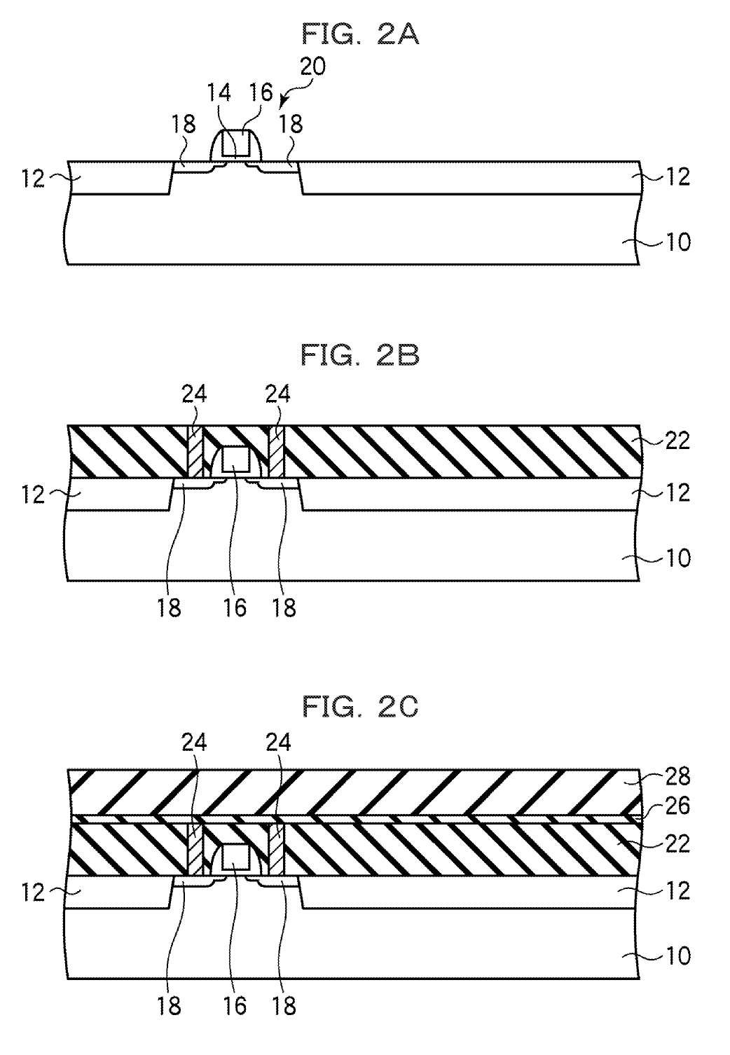

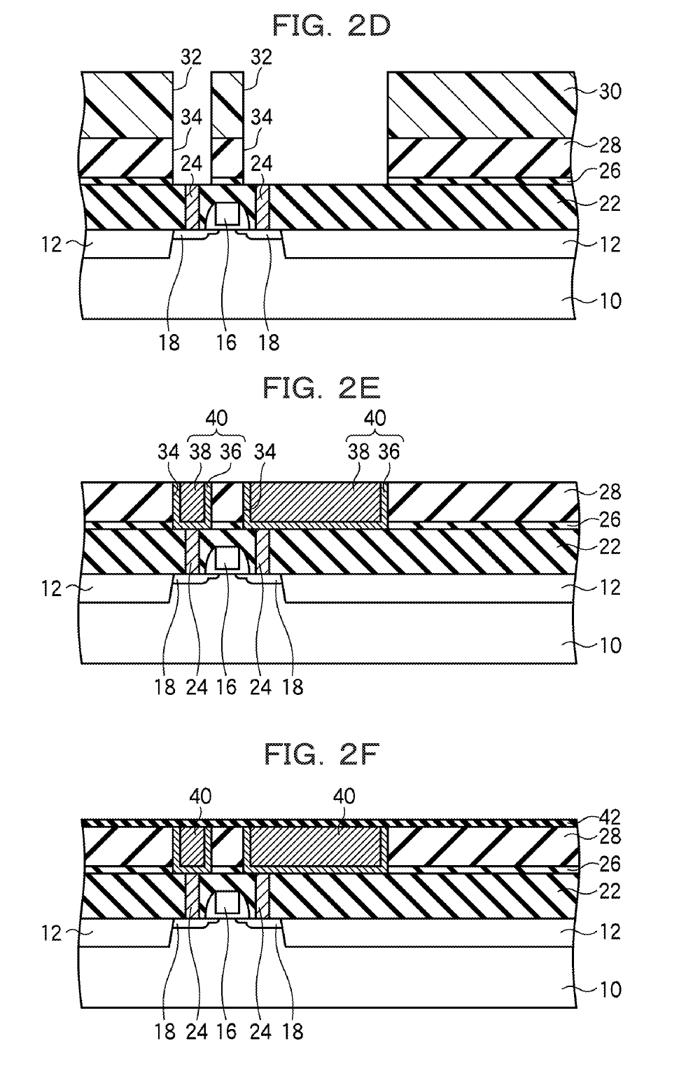

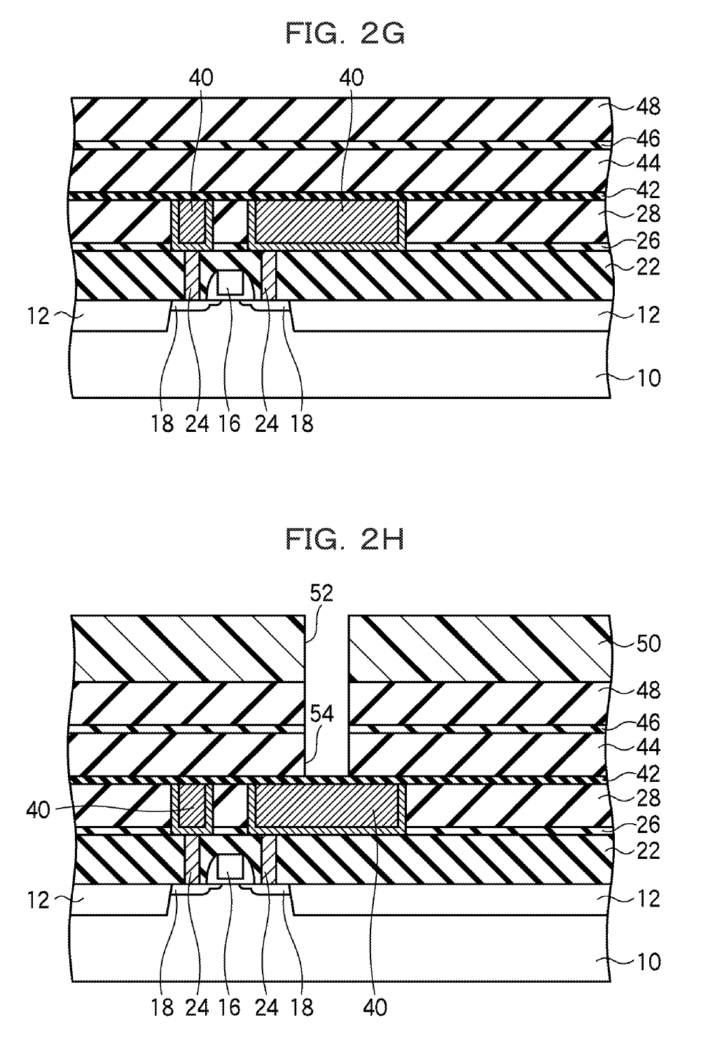

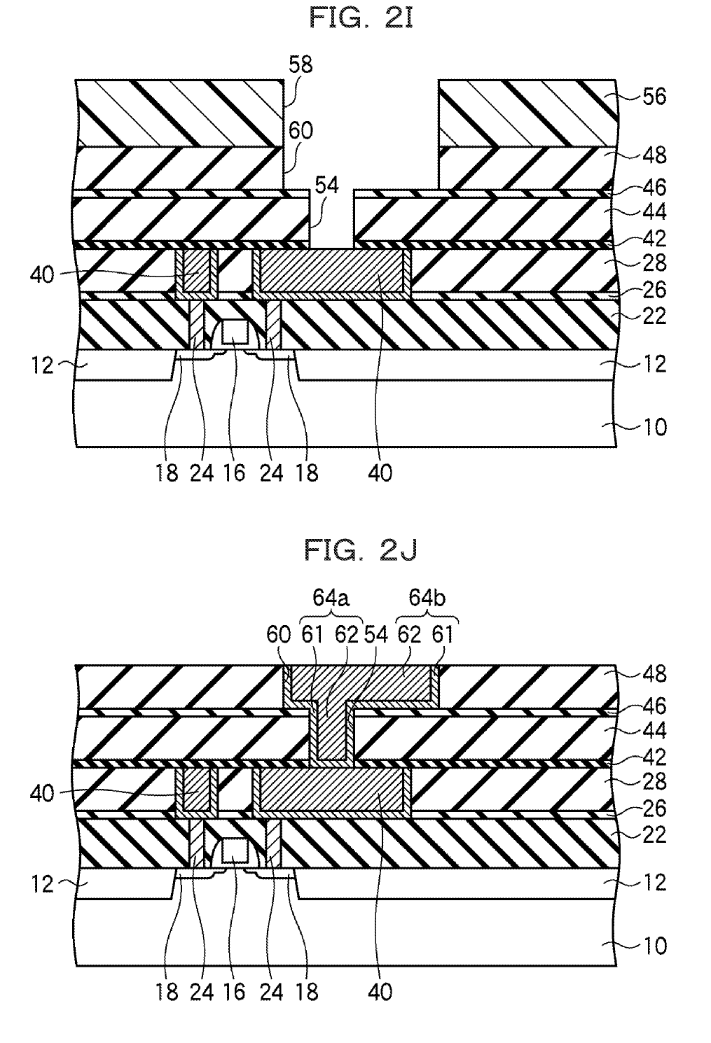

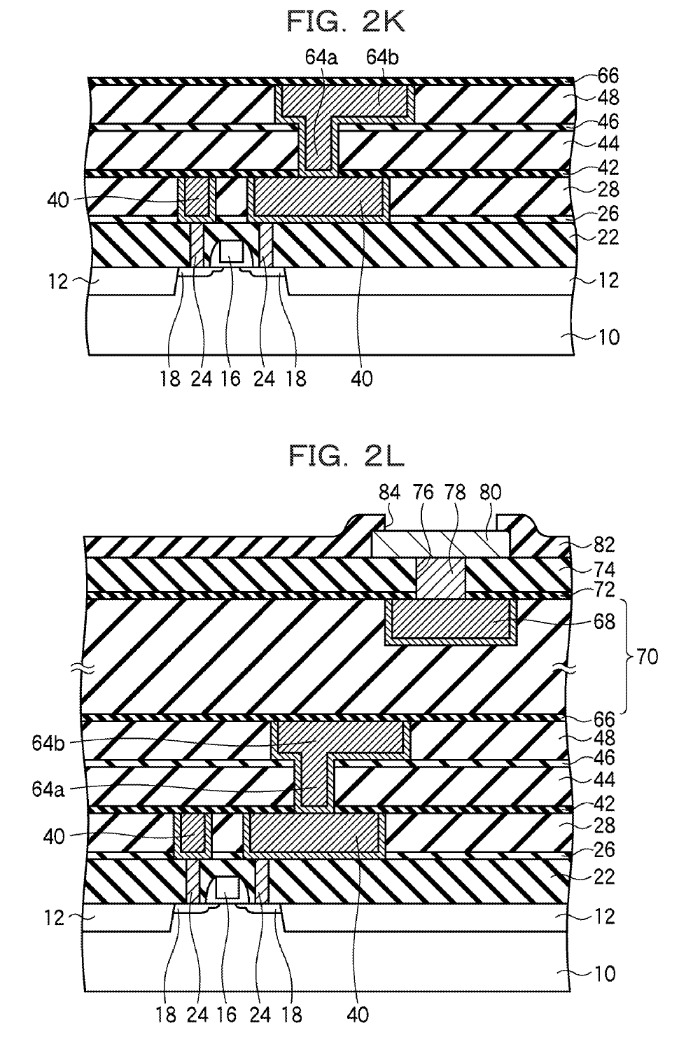

A semiconductor device and a method of manufacturing the same according to one embodiment will be described with reference to FIGS. 1 and 2A to 2L.

FIG. 1 is a schematic sectional view illustrating a structure of the semiconductor device according to the present embodiment, and FIGS. 2A to 2L are sectional views illustrating processes of a method of manufacturing the semiconductor device according to the present embodiment.

Referring first to FIG. 1, description will be made of the structure of the semiconductor device according to the present embodiment.

A device isolation insulating film 12 is buried in an obverse surface of a semiconductor substrate 10. On an active region of the semiconductor substrate 10 defined by the device isolation insulating film 12, a MIS transistor 20 is formed which includes a gate electrode 16 formed on the semiconductor substrate 10 via an intervening gate insulating film 14, and source/drain regions 18 formed in the semiconductor substrate 10 on opposite sides of the gate electrode 16.

An interlayer insulating film 22 is formed over the semiconductor substrate 10 and the MIS transistor 20. Contact plugs 24 each connected to respective source/drain regions 18 are buried in the interlayer insulating film 22.

An etching stopper film 26 and an interlayer insulating film 28 including a porous insulating material are formed over the interlayer insulating film 22 in which the contact plugs 24 are buried. Interconnection wires 40 connected to respective contact plugs 24 are buried so as to extend through the interlayer insulating film 28 and the etching stopper film 26.

On the interlayer insulating film 28 in which the interconnection wires 40 are buried, there are formed a barrier insulating film 42 including an insulating material containing a nitrogen heterocyclic compound, an interlayer insulating film 44 including the porous insulating material, an etching stopper film 46, and an interlayer insulating film 48 including the porous insulating material. A via plug 64a is buried so as to extend through the barrier insulating film 42, interlayer insulating film 44, and etching stopper film 46. An interconnection wire 64b formed integrally with the via plug 64a is buried in the interlayer insulating film 48.

A barrier insulating film 66 including the insulating material containing the nitrogen heterocyclic compound is formed over the interlayer insulating film 48 in which the interconnection wire 64b is buried. A multi-level interconnection layer 70 including an interconnection wire 68 is formed over the barrier insulating film 66.

An etching stopper film 72 and an interlayer insulating film 74 are formed over the multi-level interconnection layer 70. A contact plug 78 connected to the interconnection wire 68 is buried so as to extend through the interlayer insulating film 74 and the etching stopper film 72.

A pad electrode 80 connected to the interconnection wire 68 via the contact plug 78 is formed on the interlayer insulating film 74 in which the contact plug 78 is buried. Over the interlayer insulating film 74 formed with the pad electrode 80, a passivation film 82 is formed which has an opening 84 over the pad electrode 80.

In the semiconductor device thus structured according to the present embodiment, the barrier insulating films 42 and 66 each include the insulating material containing the nitrogen heterocyclic compound. The provision of such a barrier insulating film is to prevent a diffusion of copper (Cu), which is a major constituent of the interconnection wires 40 and 64, into the interlayer insulating film located adjacent thereto. In the insulating material containing the nitrogen heterocyclic compound, nitrogen, which has an unshared electron pair in the skeleton of the nitrogen heterocyclic compound, captures Cu and hence contributes to the prevention of Cu diffusion. Thus, the barrier insulating film functions as a barrier against Cu diffusion.

Such nitrogen heterocyclic compounds include, without particular limitation, nitrogen pentacyclic or hexacyclic compounds, or derivatives thereof. Examples of such compounds include: compounds of the type having an imidazole skeleton (e.g., polyimidazole polymers); compounds of the type having a pyrrole skeleton (e.g., polypyrrole polymers); compounds of the type having an indole skeleton (e.g., polyindole polymers); compounds of the type having a purine skeleton (e.g., polypurine polymers); compounds of the type having a pyrazole skeleton (e.g., polypyrazole polymers); compounds of the type having an oxazole skeleton (e.g., polyoxazole polymers); and compounds of the type having a thiazole skeleton (e.g., polythiazole polymers). These compounds are coating-type insulating materials each of which may be formed into a film by a coating process (e.g., SOD (Spin On Dielectric) process).

In general, a Cu diffusion preventing film includes a film grown by plasma CVD such as, for example, an SiOC film. In forming a barrier insulating film by plasma CVD, however, the interlayer insulating film which underlies the barrier insulating film is exposed to plasma during the barrier insulating film forming process. The porous insulating material, which has a relative permittivity lowered by the provision of pores therein, has a low bulk strength and is weak against plasma. Thereforewhen each of the interlayer insulating films 28 and 48 is formed using the porous insulating material as in the present embodiment, porous insulating material properties may be deteriorated by plasma generated during deposition of the barrier insulating film. For example, the porous insulating material may have an increased relative permittivity or a lower insulating property.

By using coating-type insulating films, the barrier insulating films 42 and 66 may be formed without damaging the porous insulating material interlayer insulating films 28 and 48. Each of the barrier insulating film materials mentioned above has a relative permittivity ranging from 2.7 to 3.6 for example, which is substantially equal to or less than the relative permittivity (about 3.6) of the SiOC film usually used as a barrier insulating film. Therefore, use of any one of the aforementioned barrier insulating film materials makes it possible to lower the dielectric constants of the interlayer insulating films.

Description will be made of the method of manufacturing the semiconductor device according to the present embodiment with reference to FIGS. 2A to 2L.

Initially, the device isolation insulating film 12 is formed in the semiconductor substrate 10 (e.g., a silicon substrate) by a process such as Shallow Trench Isolation (STI).

The MIS transistor 20, which includes the gate electrode 16 formed on the semiconductor substrate 10 via the intervening gate insulating film 14 and the source/drain regions 18 formed in the semiconductor substrate 10 on opposite sides of the gate electrode 16, is formed on an active region of the semiconductor substrate 10 defined by the device isolation insulating film 12 in a similar manner as a typical MIS transistor manufacturing method (see FIG. 2A).

A phosphosilicate glass (PSG) film having a thickness of 1.5 μm for example is deposited, by CVD for example, on the semiconductor substrate 10 formed with the MIS transistor 20.

The surface of the PSG film is planarized by polishing, for example Chemical Mechanical Polishing (CMP), to form the interlayer insulating film 22 having a planarized surface.

Contact holes reaching the respective source/drain regions 18 through the interlayer insulating film 22 are formed by photolithography and dry etching.

A barrier metal film, such as a titanium nitride (TiN) film having a thickness of 10 nm for example, and a tungsten (W) film having a thickness of 500 nm for example, are deposited as contact plug materials over the entire surface by, for example, sputtering.

The tungsten film and titanium nitride film on the interlayer insulating film 22 are selectively removed by, for example, CMP to form the contact plugs 24 each buried in respective contact holes and connected to respective source/drain regions 18 (see FIG. 2B).

Silicon oxycarbide (SiOC) is deposited by, for example, CVD to a film thickness of 30 nm, for example, over the interlayer insulating film 22 in which the contact plugs 24 are buried, to form the SiOC etching stopper film 26.

The interlayer insulating film 28 including the porous insulating material is formed to a thickness of 150 nm, for example, over the etching stopper film 26 by, for example, a coating process (e.g., SOD (Spin On Dielectric) process) (see FIG. 2C).

Examples of usable coating-type porous insulating materials include, without particular limitation, porous HSQ (hydrogensilsesquioxane) which is an inorganic SOG (silicon on glass) material, and porous MSG (methylsilsesquioxane) which is an organic SOG material.

Such porous insulating materials are classified into, for example, two types: a template type, which is prepared by a process including adding a heat decomposable resin or the like to the organic SOG material and allowing the heat decomposable resin to thermally decompose by heating to form pores, and a non-template type which is prepared by a process including forming silica particles in alkali and utilizing interparticle spaces to form pores. Of the two types, the non-template type is preferable because minute pores may be formed uniformly. Specific non-template type porous MSGs include NCS series products of JGC Catalysts and Chemicals Ltd., and LKD series products of JSR Corporation.

An insulating film including a coating-type insulating material may be formed, for example, by performing spin coating with an insulating film forming composition and curing the insulating film forming composition at a temperature of about 350° C. to about 450° C. An insulating film including porous MSQ may be formed, for example, by performing coating with the insulating film forming composition and then curing the insulating film forming composition at about 400° C. for about 60 minutes. The interlayer insulating film 28 including porous MSQ thus formed has a relative permittivity of about 2.4 for example.

A photoresist film 30, having openings 32 in regions for forming interconnection wire grooves for burying therein the interconnection wires to be connected to the respective contact plugs 24, is formed over the interlayer insulating film 28 by photolithography.

The interlayer insulating film 28 and the etching stopper film 26 are subjected to dry etching using the photoresist film 30 as a mask, to form interconnection wire grooves 34 each reaching one of the contact plugs 24 through the interlayer insulating film 28 and the etching stopper film 26 (see FIG. 2D).

The photoresist film 30 is removed by ashing, for example.

A tantalum (Ta) film having a thickness of 15 nm, for example, is formed over the entire surface by sputtering, for example, to form a barrier metal film 36 including the Ta film.

Copper (Cu) is deposited to a film thickness of 50 nm, for example, over the barrier metal film 36 by sputtering, for example, to form a Cu seed film (not depicted).

A Cu film is grown by, for example, electroplating using the seed film as a seed, to form a Cu film 38 having a total thickness of, for example, 300 nm inclusive of the thickness of the seed layer.

The Cu film 38 and barrier metal film 36 on the insulating film 28 are selectively removed by CMP, for example, to form the interconnection wires 40 buried in the respective interconnection wire grooves 34 (see FIG. 2E).

The surface of the interlayer insulating film 28 in which the interconnection wires 40 are buried is washed with an alcohol-type solvent or a ketone-type solvent. An alcohol-type solvent is desirably a substance which can stably maintain a liquid state at room temperature, but is not particularly limited thereto. Examples of usable alcohol-type solvents include isopropyl alcohol, ethanol, and methanol. A ketone-type solvent is desirably a substance which can stably maintain a liquid state at room temperature, but is not particularly limited thereto. Examples of usable ketone-type solvents include acetone, methyl ethyl ketone, and methyl isobutyl ketone.

The barrier insulating film 42 including the insulating material containing the nitrogen heterocyclic compound is formed by the SOD process over the interlayer insulating film 28 in which the interconnection wires 40 are buried (see FIG. 2F).

The above-described washing process using the alcohol-type solvent or ketone-type solvent serves as a pretreatment conducted prior to the deposition of the barrier insulating film 42. In cases where a film forming process other than the SOD process, such as plasma CVD, is used for the formation of a barrier insulating film, pretreatment in film deposition is possible by conducting a plasma treatment or the like prior to the film deposition. In the present embodiment on the other hand, the surface over which the barrier insulating film 42 is to be formed is cleaned by washing using the alcohol-type solvent or ketone-type solvent to allow the barrier insulating film 42 to be formed by the SOD process.

The SOD process is used for the formation of the barrier insulating film 42 so that the barrier insulating film 42 may be formed without damaging the porous insulating material interlayer insulating film 28.

The barrier insulating film 42, which is a film for preventing diffusion of Cu from the interconnection wires 40, is usually an insulating film having a high density. A film grown by plasma CVD, for example, an SiOC film is typically used for such an insulating film. In forming such a barrier insulating film by plasma CVD, however, the interlayer insulating film which underlies the barrier insulating film is exposed to plasma during the barrier insulating film forming process.

The porous insulating material, which has a relative permittivity lowered by the provision of pores therein, has a low bulk strength due to the provision of pores and is weak against plasma. Therefore, when the interlayer insulating film 28 is formed using the porous insulating material as in the present embodiment, the porous insulating material might have properties deteriorated by plasma generated during deposition of the barrier insulating film. For example, the porous insulating material might have an increased relative permittivity or a lower insulating property.

The present embodiment uses the SOD process for the formation of the barrier insulating film 42 because the SOD process does not damage the underlying material during the film forming process.

Nitrogen heterocyclic compounds may include, without particular limitation, compounds of the type having an imidazole skeleton (e.g., polyimidazole polymers), compounds of the type having a pyrrole skeleton (e.g., polypyrrole polymers), compounds of the type having an indole skeleton (e.g., polyindole polymers), compounds of the type having a purine skeleton (e.g., polypurine polymers), compounds of the type having a pyrazole skeleton (e.g., polypyrazole polymers), compounds of the type having an oxazole skeleton (e.g., polyoxazole polymers), and compounds of the type having a thiazole skeleton (e.g., polythiazole polymers). The barrier insulating film is formed using the insulating material containing the nitrogen heterocyclic compound because the presence of nitrogen having an unshared electron pair in the skeleton of the nitrogen heterocyclic compound contributes to the prevention of Cu diffusion.

The following is an example of a method of forming the barrier insulating film 42 including a polyimidazole polymer.

Initially, a barrier insulating film forming composition is prepared which includes 1,3,5-tricarboxyladamantane as a first monomer, N,N,N-triisopropylidenebiphenyl-1,3,4,3′-tetraamine as a second monomer, and a solvent.

Examples of usable first monomers include, without particular limitation, adamantane derivatives of the type having at least one carboxyl group. Examples of such adamantane derivatives include 1-carboxyladamantane derivatives, 1,3-dicarboxyladamantane derivatives, 1,3,5-tricarboxyladamantane derivatives, and 1,3,5,7-tetracarboxyladamantane derivatives. These adamantane derivatives may be used as mixtures. Examples of usable second monomers include, without particular limitation, diamine derivatives of the type having at least two amino groups, triamine derivatives, and tetraamine derivatives.

The barrier insulating film forming composition thus prepared is applied onto the interlayer insulating film 28 in which the interconnection wires are buried with use of a spin-coater.

The barrier insulating film forming composition is polymerized and cured by a heat treatment at a temperature ranging from 350° C. to 450° C. (for example, 400° C.) for an hour using a hot plate. In this way, the barrier insulating film 42 including the polyimidazole polymer is formed which has a thickness of about 20 to about 50 nm (for example, 30 nm).

In forming the barrier insulating film 42, irradiation with ultraviolet rays may be conducted in addition to the heat treatment. Irradiation with ultraviolet rays contributes to acceleration of the polymerization reaction of the barrier insulating film forming composition. Applicable ultraviolet rays include short-wavelength ultraviolet rays and broadband ultraviolet rays having multiple wavelengths from 150 to 500 nm. For example, an ultraviolet ray having wavelengths of 185 nm and 254 nm and an electron energy ranging from 4.9 to 6.7 eV may be used.

The barrier insulating film forming composition used in the present embodiment does not contain sacrificial organic molecules as contained in the template-type porous insulating material. A material containing sacrificial organic molecules allows pores to be formed in the resulting film when the sacrificial organic molecules come out of the film. The barrier insulating film forming composition used in the present embodiment, on the other hand, does not contain sacrificial organic molecules and hence does not allow pores to be formed in the resulting barrier insulating film 42. In the present description, a film having no pores formed therein is referred to as a “continuous film”.

The barrier insulating film 42 of the polyimidazole polymer thus formed has a relative permittivity of about 2.9, which is lower than 3.6, which is the relative permittivity of a typical SiOC film.

The interlayer insulating film 44 including the porous insulating material is formed by the SOD process, for example, to a thickness of 150 nm, for example, over the barrier insulating film 42. The interlayer insulating film 44 may be formed using the same method and material as used for the formation of the above-described interlayer insulating film 28.

An SiOC film having a thickness of 30 nm, for example, is deposited over the interlayer insulating film 44 by plasma CVD, for example, to form the etching stopper film 46 including the SiOC film.

The interlayer insulating film 48 including the porous insulating material is formed to a thickness of 150 nm, for example, over the etching stopper film 46 by the SOD process, for example, (see FIG. 2G). The interlayer insulating film 48 may be formed using the same method and material as used for the formation of the above-described interlayer insulating film 28.

A photoresist film 50 having an opening 52 in a region to form a via hole to be connected to the interconnection wire 40 is formed over the interlayer insulating film 48 by photolithography.

The interlayer insulating film 48, etching stopper film 46, and interlayer insulating film 44 are sequentially subjected to dry etching using the photoresist film 50 as a mask to form a via hole 54 reaching the barrier insulating film 42 (see FIG. 2H).

The presence of nitrogen in the barrier insulating film 42 including the polyimidazole polymer allows for etching selectivity between the interlayer insulating film 44 including the porous insulating material and the barrier insulating film 42. In etching the interlayer insulating film 48, the etching stopper film 46, and the interlayer insulating film 44, use of C₄F₆ gas, for example, may ensure a selection ratio of about 10 for the barrier insulating film 42.

The photoresist film 50 may be removed by, for example, ashing.

A photoresist film 56 having an opening 58 in a region to form an interconnection wire groove for burying therein an interconnection wire to be connected to the via hole 54, is formed over the interlayer insulating film 48 by photolithography.

The interlayer insulating film 48 is subjected to dry etching using the photoresist film 56 as a mask and the etching stopper film 46 as a stopper, to form an interconnection wire groove 60 reaching the etching stopper film 46 through the interlayer insulating film 48.

The barrier insulating film 42 is subjected to dry etching using the photoresist film 56 and the etching stopper film 46 as masks to extend the via hole 54 down to the interconnection wire 40 (see FIG. 2I). The barrier insulating film 42 may be selectively etched relative to the interlayer insulating films 44 and 48 and etching stopper film 46 by using, for example, a fluorine compound containing nitrogen.

The photoresist film 56 is removed by ashing, for example.

Ta is deposited to a film thickness of 15 nm, for example, over the entire surface by sputtering, for example, to form a Ta barrier metal film 61.

Copper (Cu) is deposited to a film thickness of 50 nm, for example, over the barrier metal film 61 by sputtering, for example, to deposit a Cu seed film (not depicted).

A Cu film is grown by, for example, electroplating using the seed film as a seed to form a Cu film 62 having a total thickness of, for example, 300 nm inclusive of the thickness of the seed layer.

The Cu film 62 and barrier metal film 61 on the interlayer insulating film 48 are selectively removed by CMP, for example, to integrally form the via plug 64a buried in the via hole 54 and the interconnection wire 64b buried in the interconnection wire groove 60 (see FIG. 2J). A fabrication process for integrally forming the via plug 64a and the interconnection wire 64b is called a “dual damascene process”.

The surface of the interlayer insulating film 48 in which the interconnection wire 64b is buried is washed with an alcohol-type solvent or a ketone-type solvent. This process is the same as the pretreatment process performed prior to the formation of the above-described barrier insulating film 42.

The barrier insulating film 66 including the insulating material containing the nitrogen heterocyclic compound is formed over the interlayer insulating film 48 in which the interconnection wire 64b is buried in the same manner as the method of forming the barrier insulating film 42, for example (see FIG. 2K).

Thereafter, the multi-level interconnection layer 70 including an interconnection wire is formed by an interconnection wire forming process similar to the above-described process.

The SiOC etching stopper film 72, for example, and the silicon oxide film interlayer insulating film 74 are formed over the multi-level interconnection layer 70 by, for example, CVD.

A contact hole 76 reaching the interconnection wire 68 through the interlayer insulating film 74 and the etching stopper film 72 is formed by photolithography and dry etching.

The contact plug 78 connected to the interconnection wire 68 is formed in the contact hole 76 in the same manner as the method of forming the contact plug 24 for example.

An aluminum (Al) film is formed by sputtering, for example, over the interlayer insulating film in which the contact plug is buried.

The aluminum film is patterned by photolithography and dry etching to form the pad electrode 80 connected to the interconnection wire 68 via the contact plug 78.

Silicon nitride is deposited by CVD, for example, over the interlayer insulating film 74 formed with the pad electrode 80, to form the silicon nitride passivation film 82.

The opening 84 exposing an electrode pad is formed in the passivation film 82 by photolithography and dry etching.

In this way, the semiconductor device depicted in FIG. 1 according to the present embodiment is manufactured.

The present embodiment described above may reduce damage to an insulating film including the porous material during formation of a barrier insulating film for preventing diffusion of copper from interconnection wires. Thus, it is possible to reduce if not prevent a rise in the dielectric constant of the insulating film including the porous material and deterioration in the insulating property of the insulating film, thereby to realize a semiconductor device having a low interconnect capacitance and a high insulating property.

### Variation Embodiments

The present embodiment is not limited to the foregoing embodiment, but variations are possible.

For example, while the foregoing embodiment conducts the washing treatment using the alcohol-type solvent or the ketone-type solvent as the pretreatment prior to the formation of each of the barrier insulating films 42 and 66 including the insulating material containing the nitrogen heterocyclic compound, the present embodiment does not necessarily require the washing treatment.

While the foregoing embodiment uses the SiOC film formed by plasma CVD as an intermediate stopper layer (i.e., etching stopper film 46) to be used in the dual damascene process, an insulating material containing the nitrogen heterocyclic compound like the insulating material used to form the barrier insulating films 42 and 66 may be used to form the intermediate stopper layer. By so doing, it is possible to reduce damage to the interlayer insulating film 44 which occurs during the formation of the etching stopper film 46.

The present embodiment is not limited to the structure of the semiconductor device or the method of manufacturing the same disclosed in the foregoing embodiment. The present embodiment is widely applicable to the production of semiconductor devices of the type having a copper interconnection wire buried in a porous insulating film formed over an underlying substrate. The film thickness and the material of each of the layers forming the semiconductor device may be varied appropriately.

It is to be noted that the “underlying substrate”, as used herein, is meant to include not only a semiconductor substrate as made, such as a silicon substrate, but also a semiconductor device formed with a device, such as a transistor, and an interconnection layer.

### Embodiment 1

A semiconductor device was manufactured according to the manufacturing process described in the foregoing embodiment using a polyimidazole polymer for the barrier insulating films 42 and 66 and “NCS” (relative permittivity: 2.4) produced by JGC Catalysts and Chemicals Ltd. for the interlayer insulating films 28 and 44.

The semiconductor device thus produced was measured for leakage current by application of a voltage of 2 V to interconnection wires of a comb-toothed shape (total length of opposed interconnection wires: 200,000 μm) having a line-and-space (L/S) of 70/70 nm and a thickness of 130 nm. The leakage current thus measured was not more than 1×10⁻¹⁴ A, which proved that the semiconductor device had a favorable leakage current characteristic. The semiconductor device had an interconnect capacitance of 0.10 pF.

### COMPARATIVE EXAMPLE 1

A semiconductor device was produced in the same manner as in Example 1 except that an SiOC film deposited by CVD using tetramethylsilane and carbon dioxide gas was used for each of the barrier insulating films 42 and 66.

The semiconductor device thus produced was measured for leakage current by application of a voltage of 2 V to interconnection wires of a comb-toothed shape (total length of opposed interconnection wires: 200,000 μm) having a line-and-space (L/S) of 70/70 nm and a thickness of 130 nm. The leakage current thus measured was about 1×10⁻⁷ A, which proved that interconnect leakage occurred. The semiconductor device had an interconnect capacitance of 0.13 pF.

### Embodiment 2

A semiconductor device was produced according to the manufacturing process described in the foregoing embodiment using a polyimidazole polymer for the barrier insulating films 42 and 66 and “Aurora ULK” (relative permittivity: 2.6) produced by ASM Japan K.K. for the interlayer insulating films 28 and 44.

The semiconductor device thus produced was measured for leakage current by application of a voltage of 2 V to interconnection wires of a comb-toothed shape (total length of opposed interconnection wires: 200,000 μm) having a line-and-space (L/S) of 70/70 nm and a thickness of 130 nm. The leakage current thus measured was not more than 1×10⁻¹⁴ A, which proved that the semiconductor device had a favorable leakage current characteristic. The semiconductor device had an interconnect capacitance of 0.12 pF.

### COMPARATIVE EXAMPLE 2

A semiconductor device was produced in the same manner as in Example 1 except that an SiOC film deposited by CVD using tetramethylsilane and carbon dioxide gas was used for each of the barrier insulating films 42 and 66.

The semiconductor device thus produced was measured for leakage current by application of a voltage of 2 V to interconnection wires of a comb-toothed shape (total length of opposed interconnection wires: 200,000 μm) having a line-and-space (L/S) of 70/70 nm and a thickness of 130 nm. The leakage current thus measured was about 1×10⁻⁷ A, which proved that interconnect leakage occurred. The semiconductor device had an interconnect capacitance of 0.14 pF.

### Embodiment 3

Using the manufacturing process described in the foregoing embodiment, a semiconductor device produced without conducting a washing treatment using an alcohol-type solvent or a ketone-type solvent prior to the formation of each of the barrier insulating films 42 and 66 and a semiconductor device manufactured by conducting the washing treatment using the alcohol-type solvent or the ketone-type solvent prior to the formation of each of the barrier insulating films 42 and 66, were provided.

These semiconductor devices were each measured for the I-V characteristic of a comb-toothed pattern having a W/S of 90/90 nm at randomly selected points in the plane of a wafer having a diameter of 300 mm. As a result, both of the semiconductor devices exhibited favorable I-V characteristics. As a result, the semiconductor device manufactured by conducting the washing treatment using the alcohol-type solvent and the semiconductor device manufactured using the ketone-type solvent both exhibited reduced variations in I-V characteristics.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A semiconductor device comprising:
an insulating film including a porous insulating material and formed above a substrate;
an interconnection wire including copper and buried in a groove formed at least in an obverse surface of the insulating film; and
a barrier insulating film including an insulating material containing a nitrogen heterocyclic compound and formed over the insulating film and the interconnection wire.

2. The semiconductor device according to claim 1, wherein the barrier insulating film is a coating-type insulating material.

3. The semiconductor device according to claim 1, wherein the nitrogen heterocyclic compound is a compound selected from a group including a compound having an imidazole skeleton, a compound having a pyrrole skeleton, a compound having an indole skeleton, a compound having a purine skeleton, a compound having a pyrazole skeleton, a compound having an oxazole skeleton, and a compound having a thiazole skeleton.

4. The semiconductor device according to claim 1, wherein the barrier insulating film is a continuous film.

5. A method of manufacturing a semiconductor device comprising:
forming an insulating film including a porous insulating material above a substrate;
forming an opening in the insulating film;
forming an interconnection wire including copper in the opening; and
forming a barrier insulating film including an insulating material containing a nitrogen heterocyclic compound over the insulating film and the interconnection wire.

6. A method of manufacturing a semiconductor device according to claim 5, wherein the barrier insulating film is formed by performing coating with an insulating film forming composition and then hardening the insulating film forming composition.

7. A method of manufacturing a semiconductor device according to claim 5, wherein the barrier insulating film is formed from the insulating material containing the nitrogen heterocyclic compound which is a compound selected from a group including a compound having an imidazole skeleton, a compound having a pyrrole skeleton, a compound having an indole skeleton, a compound having a purine skeleton, a compound having a pyrazole skeleton, a compound having an oxazole skeleton, and a compound having a thiazole skeleton.

8. A method of manufacturing a semiconductor device according to claim 5, further comprising washing with an alcohol-type solvent or a ketone-type solvent after the formation of the interconnection wire and before the formation of the barrier insulating film.

9. A method of manufacturing a semiconductor device according to claim 8, wherein the alcohol-type solvent is isopropyl alcohol, ethanol, or methanol.

10. A method of manufacturing a semiconductor device according to claim 8, wherein the ketone-type solvent is acetone, methyl ethyl ketone, or methyl isobutyl ketone.
